(19) United States
(12) Patent Application Publication
(10) Pub. No.: US 2023/0317510 A1
(43) Pub. Date: Oct. 5, 2023

(54) METHOD FOR BONDING A FIRST SUBSTRATE AT A SURFACE HAVING AN ELASTIC NANOTOPOLOGY

(71) Applicant: COMMISSARIAT À L’ENERGIE ATOMIQUE ET AUX ENERGIES ALTERNATIVES, PARIS (FR)

(72) Inventors: Frank FOURNEL, GRENOBLE CEDEX 09 (FR); Karine ABADIE, GRENOBLE CEDEX 09 (FR)

(21) Appl. No.: 18/194,977

(22) Filed: Apr. 3, 2023

(30) Foreign Application Priority Data
Apr. 4, 2022 (FR) 2203033

(51) Int. Cl. H01L 21/762

(52) U.S. Cl. CPC H01L 21/76251

(57) ABSTRACT

A method for bonding a first substrate to a second substrate, the first substrate including, prior to bonding, a support layer, the method including removing the support layer to free a first surface substrate, thereby forming an elastic nanotopology on the first surface; stripping the first surface with rare gas atoms or depositing a thin film of metal or semiconductor onto the first surface; thermocompression bonding the first substrate to the second substrate, the contact between the first substrate and the second substrate being made at the first surface and a second surface of the second substrate, this bonding being carried out using an atomic diffusion bonding technique or a surface activation bonding technique. The stripping or deposition and the bonding step are performed under ultra-high vacuum. The pressure is between 1 and 100 kN and the temperature is between 200° C. and 600° C. in the thermocompression bonding.

### CROSS-REFERENCE TO RELATED APPLICATIONS

This application claims priority to French Patent Application No. 2203033, filed Apr. 4, 2022, the entire content of which is incorporated herein by reference in its entirety.

### FIELD

The technical field of the invention is that of thermocompression bonding substrates.

The present invention relates to a thermocompression bonding method and in particular to a method for thermocompression bonding a substrate having a surface with an elastic nanotopology as a result of the removal of a support layer.

### BACKGROUND

Direct bonding is a technique that is now well known and used for industrial applications such as the manufacture of SOI (Silicon On Insulator) or the production of imagers for example. Direct bonding is a spontaneous bonding between two surfaces without the addition of material, especially without a thick layer of liquid. It is nevertheless possible to have a few water monolayers adsorbed on the surfaces, but these are macroscopically dry. The surfaces to be bonded by a direct bonding method have to meet very strict specifications. In particular, they have to be very smooth (especially a roughness of less than 0.5 nm RMS measured with an AFM (Atomic Force Microscopy) on a 1×1 μm² scan), very flat and, in general, have an adapted surface chemistry.

Using thermocompression for direct bonding generally makes it possible to relax the restrictions in terms of surface preparation and especially in terms of roughness. Nevertheless, the inventors have shown that for certain surface nanotopologies induced by structures under the surfaces to be bonded, it is not possible to use thermocompression bonding to obtain good quality bonding. Indeed, the thermocompression machines used for such bonding can deliver uniaxial pressures of 50 kN to 100 kN on plates with a diameter of 200 mm, but the pressure distribution does not allow the nanotopology to be elastically overcome in order to bond the entire surface. The surfaces may even come off completely when the pressure is released.

This is especially the case for nanotopologies induced by localised internal stresses during the removal of a support layer, for example the removal of the silicon layer on the rear face of an SOI substrate. These nanotopologies are referred to as elastic nanotopologies in the following.

Therefore, in order to overcome the presence of these nanotopologies and to allow a defect-free bonding, the most common technique consists in depositing a layer of material (very often silicon oxide) and in carrying out planarisation by a chemical mechanical polishing (CMP) such that this nanotopology is overcome, which makes direct bonding sometimes complex.

Thus, there is a need for a bonding method that makes it possible, for at least certain nanotopologies, to bond two surfaces without having to resort to a planarisation step at the surfaces to be bonded, or even without having to resort to depositing a layer of material at the surface to be bonded.

### SUMMARY

An aspect of the invention offers a solution to the problems previously discussed in the case of elastic nanotopology, by allowing bonding without planarisation, the method according to the invention using pressure during thermobonding to reduce the elastic nanotopology, the bonding being preceded by a step of surface preparation under ultra-high vacuum by stripping the surface with rare gas atoms or by depositing a thin film of metal or semiconductor.

These preparation steps are similar to those otherwise implemented in SAB (Surface Activated Bonding) and ADB (Atomic Diffusion Bonding). These bonding techniques are direct covalent bonding techniques which consist in implementing covalent bonding techniques directly at the time of direct bonding. This is possible by creating dangling bonds under ultra-high vacuum (pressure<10⁻⁸ mbar or about <10⁻⁶ Pa) either for SAB using stripping of the surface with rare gas atoms (very often argon) or for ADB by depositing a very thin film (often less than 10 nm) of metal or semiconductor such as silicon for example. These bonding techniques are carried out at low temperature, typically below 200° C. or even, mainly, at room temperature.

For this, one aspect of the invention relates to a method for bonding a first substrate to a second substrate, the first substrate comprising, prior to bonding, a support layer, the method comprising:
a step of removing the support layer from the first substrate so as to free a first surface of the first substrate, said removal resulting in the formation of an elastic nanotopology on the first surface of the first substrate;
a step of stripping the first surface with rare gas atoms or depositing a thin film of metal or semiconductor onto the first surface; and
a step of thermocompression bonding the first substrate against the second substrate, the contact between the first substrate and the second substrate being made at the first surface and a second surface of the second substrate, said bonding step being carried out using an atomic diffusion bonding technique (hereinafter referred to as ADB) when a thin film deposition step has been performed or a surface activation bonding technique (hereinafter referred to as SAB) when a stripping step has been performed.

Additionally, in an embodiment of the method according to the invention, the stripping or deposition and thermocompression bonding steps are carried out under ultra-high vacuum (that is, at a pressure<10⁻⁸ mbar).

Furthermore, in an embodiment of the method according to the invention, during the thermocompression bonding step, the pressure is between 1 and 100 kN and the temperature is between room temperature and 600° C. or even between 100° C. and 300° C.

By thin film, it is meant a layer whose thickness is less than or equal to 50 nm, for example less than or equal to 10 nm, or even less than or equal to 2 nm and whose thickness is greater than or equal to 0.1 nm, for example greater than or equal to 0.5 nm. By means of the invention, it is possible to bond a surface having an elastic nanotopology with characteristics normally incompatible with direct bonding without resorting to chemical mechanical polishing, or even without resorting to depositing a layer of material at the surface to be bonded, for example when the first surface is made of silicon (without any oxide on its surface) and the second surface is also made of silicon.

In addition to the characteristics just discussed in the preceding paragraph, the method according to one or more embodiments of the invention may have one or more of the following additional characteristics, considered individually or according to any technically possible combination.

In an embodiment, during the thermocompression bonding step, the pressure is between 30 kN and 50 kN.

In an embodiment, during the thermocompression bonding step, the temperature is between 100° C. and 300° C.

In an embodiment, the bonding step is carried out using an atomic diffusion bonding technique and the thin film deposited in the thin film deposition step is a thin film of silicon, germanium, titanium, tungsten, nickel or copper (this list is not exhaustive).

In an embodiment, the bonding step is performed using a surface activation bonding technique and the surface activation is carried out using a rare gas selected from argon, helium, neon or xenon.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 shows a flow chart of a method according to the invention.

FIG. 2A, FIG. 2B and FIG. 2C illustrate the different steps of the method according to the invention.

### DETAILED DESCRIPTION

Unless otherwise specified, a same element appearing in different figures has a single reference.

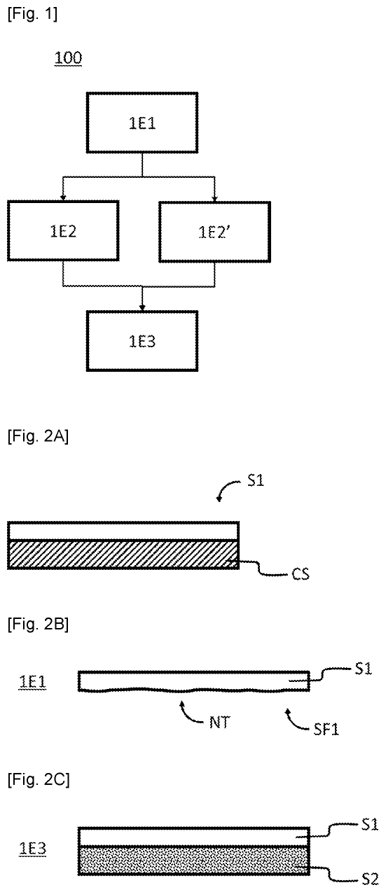

An aspect of the invention illustrated in [FIG. 1], [FIG. 2A] to [FIG. 2C] relates to a method 100 for bonding a first substrate S1 to a second substrate S2, the first substrate S1 initially, that is, prior to bonding, comprising a support layer CS. A support layer CS is understood here as a layer (which may comprise one or more sub-layers) intended to be removed prior to the thermocompression bonding step 1E2 and producing, during this removal, an elastic nanotopology NT at a surface SF1 of the first substrate, called the first surface SF1 in the following.

In an embodiment, the first substrate S1 is a silicon on insulator (SOI) wafer, on which CMOSs and one or more connection levels have been made. In this case, the support layer CS is the silicon layer located under the buried oxide (or BOX) layer of the SOI substrate. Similarly, in an embodiment, the second substrate S2 is a silicon wafer, for example an SOI type wafer, on which CMOSs and one or more connection levels have been made, and having, at the surface intended to be bonded, a topology compatible with direct bonding or else an elastic topology as previously introduced.

Example of Implementation

In an example of embodiment which will serve in the following to illustrate the method according to the invention, the first substrate S1 is an SOI type silicon wafer with a diameter of 200 mm, whose buried oxide is about 400 nm thick and on which CMOSs as well as one or more electrical interconnections levels (for example four levels) are made. This silicon wafer has; at the surface on which the CMOSs are made; a surface nanotopology with an amplitude of 200 nm over a width of 50 μm and a period of about 2 cm. These are the future paths for cutting CMOS chips.

Removal of the Support Layer

As illustrated in [FIG. 2B], the method 100 first comprises a step 1E1 of removing the support layer CS from the first substrate S1 so as to free a first surface SF1 of the first substrate S1, the removal resulting in the formation of an elastic nanotopology NT on the surface SF1 considered. This step 1E1 may for example be implemented using an intermediate substrate, sometimes called a handle.

The elastic nanotopology formed during this step 1E1 is due to localised internal stresses: in the example of embodiment previously introduced and repeated below, this elastic topology is induced by the formation of the CMOSs on the front face (that is, the face opposite the first surface SF1) of the first substrate S1. More generally, for an elastic nanotopology NT according to the invention to appear upon removal of the support layer CS, it is sufficient for the first substrate S1 to have undergone, while the support layer CS was still present, one or more method steps, for example one or more CMOS method steps.

Example of Implementation

In the example of embodiment already introduced, this removal step 1E1 is carried out using an intermediate substrate (here a silicon wafer) and comprises several sub-steps.

It first comprises a sub-step of depositing a layer of silicon oxide, for example having a thickness of 800 nm, at the surface comprising the CMOSs, that is, the surface opposite the support layer CS to be removed.

It then comprises a sub-step of chemically mechanically polishing (or CMP) the previously deposited oxide layer, for example a CMP of 600 nm, this sub-step making it possible to make up for surface irregularities induced by the nanotopology present on the surface onto which the oxide layer has been deposited.

It then comprises a sub-step of directly bonding the first substrate S1 to a silicon wafer (or handle) followed by an annealing sub-step, for example annealing at 400° C. for 2 hours.

It also comprises a sub-step of removing the silicon layer (acting here as a support layer CS) from the substrate SOI, this removal sub-step being performed in three phases: a grinding phase, for example up to 50 μm, a first chemical etching phase based on HF/HNO₃ to leave only 5 μm of silicon, and finally a second chemical etching phase using a 12.5% TMAH solution, at 50° C. for a few minutes to remove the remaining silicon layer (or support layer CS) by stopping etching on the rear face of the buried oxide of the SOI, exposing here the first SF1 surface according to the invention.

TMAH makes it possible to have an oxide surface with a roughness measured by AFM on a 1×1 μm² scan of less than 0.5 nm RMS, that is, a surface compatible with direct bonding. However, due to the removal of the silicon support layer CS, an elastic nanotopology of up to a few tens of nanometres appears on the rear face, that is, at the first surface SF1 according to the invention, making direct bonding without CMP impossible on this surface SF1.

Stripping or Deposition of a Thin Film

The method according to an embodiment of the invention then comprises a step 1E2 of stripping the first surface SF1 with rare gas atoms or depositing a thin film onto the first surface SF1.

Example of Implementation

Within the scope of the example of implementation used so far, this stripping or deposition step 1E2 may be implemented according to at least two different modes.

First Implementation Mode

In a first implementation mode, during this step 1E2, a thin layer, for example with a thickness of between 5 and 10 nm, of amorphous silicon is deposited onto the first surface SF1 at 400° C. In an embodiment, this step is followed by a degassing annealing carried out at 450° C. for one hour.

Then, stripping the first surface SF1 is implemented under ultra-high vacuum to expose the silicon layer by removing its native oxide.

Second Implementation Mode

In a second implementation mode, in this step 1E2, a 10 nm thick silicon layer is deposited under ultra-high vacuum onto the first surface SF1.

Thermocompression Bonding

As illustrated in [FIG. 2C], the method 100 according to the invention then comprises a step 1E3 of thermocompression bonding the first substrate S1 to the second substrate S2, the contact between the first substrate S1 and the second substrate S2 being made at the first surface SF1 of the first substrate S1 and a second surface of the second substrate S2. Additionally, during this thermocompression bonding step 1E3, the pressure applied is between 1 and 100 kN, and in an embodiment between 30 kN and 50 kN, and the temperature is between room temperature and 600° C., and in an embodiment between 100° C. and 300° C.

In an embodiment, the thermocompression bonding step is carried out using an SAB bonding technique. In an embodiment, the surface activation of the SAB technology is carried out using a rare gas, for example selected from argon, helium, neon or xenon.

In an alternative embodiment, the thermocompression bonding step is carried out using an ADB bonding technique, using a layer of silicon or a layer of metal such as tungsten (W) or titanium (Ti).

Example of Implementation

Within the scope of the example of implementation used so far, this thermocompression bonding step 1E3 can be implemented in at least two different modes.

First Implementation Mode

In the first implementation mode already introduced, the bonding step 1E3 is carried out using a surface activation bonding technique SAB on a silicon wafer (or a wafer having undergone one or more manufacturing method steps that has a layer that can be bonded by direct bonding at the surface and is compatible with the SAB technology) acting as a second substrate S2 according to the invention. More particularly, in this example of embodiment, after the step 1E2 of depositing a thin layer of silicon, the method comprises a bonding step 1E3 with activation of the first surface SF1 and the second surface SF2 by an argon beam of 200 eV, 150 mA followed by the actual bonding carried out by applying a pressure of 50 kN and a temperature of 300° C. while remaining under ultra-high vacuum. The structure obtained at the end of the method according to the invention does not have the bonding defects that the elastic nanotopology present at the first surface SF1 of the first substrate S1 should have generated.

Second Implementation Mode

In the second implementation mode already introduced, the thermocompression bonding step 1E3 is carried out by an ADB method on a silicon wafer (or a wafer that has undergone one or more manufacturing method steps that has a layer that can be bonded by direct bonding at the surface and is compatible with the ADB technology) acting as the second substrate S2 according to an embodiment of the invention. More particularly, in this example of embodiment, at the end of step 1E2 of depositing a 10 nm thick silicon layer onto the first surface SF1, which is itself carried out under ultra-high vacuum as previously described, the method comprises, while maintaining the ultra-high vacuum, a bonding step 1E3 by bringing the substrates S1, S2 into contact by applying a pressure of 50 kN and a temperature of 300° C. As for the first implementation mode, the structure obtained at the end of the method 100 according to an embodiment of the invention does not have bonding defects that the elastic nanotopology present at the first surface SF1 of the first substrate S1 should have generated.

As just detailed, the method 100 according to the invention makes it possible to bond a surface SF1 having a topology normally incompatible with direct bonding when this topology is an elastic topology. In addition, this bonding can be performed without resorting to chemical mechanical polishing, or even without resorting to depositing a layer of material onto the surface to be bonded.

It will be appreciated that the various embodiments described previously are combinable according to any technically permissible combinations.

The articles “a” and “an” may be employed in connection with various elements and components of processes or structures described herein. This is merely for convenience and to give a general sense of the processes or structures. Such a description includes “one or at least one” of the elements or components. Moreover, as used herein, the singular articles also include a description of a plurality of elements or components, unless it is apparent from a specific context that the plural is excluded.

1. A method for bonding a first substrate to a second substrate, the first substrate comprising, prior to bonding, a support layer, the method comprising:
removing the support layer from the first substrate so as to free a first surface of the first substrate, said removal resulting in the formation of an elastic nanotopology on the first surface of the first substrate;
stripping the first surface with rare gas atoms or depositing a thin film of metal or semiconductor onto the first surface;
thermocompression bonding the first substrate to the second substrate, the contact between the first substrate and the second substrate being made at the first surface and a second surface of the second substrate, said thermocompression bonding being carried out using an atomic diffusion bonding technique when a thin film deposition step has been performed or a surface activation bonding technique when a stripping step has been performed;
wherein the stripping or depositing and the thermocompression bonding are performed under ultra-high vacuum, a pressure being between 1 and 100 kN and a temperature being between room temperature and 600° C. during the thermocompression bonding.

2. The method according to claim 1, wherein during the thermocompression bonding, the pressure is between 30 kN and 50 kN.

3. The method according to claim 1, wherein during the thermocompression bonding, the temperature is between 100° C. and 300° C.

4. The method according to claim 1, wherein the thermocompression bonding is carried out by a surface activation bonding technique and the surface activation is carried out by a rare gas selected from argon, helium, neon or xenon.

5. The method according to claim 1, wherein the thermocompression bonding is carried out using an atomic diffusion bonding technique and wherein the thin film deposited in the thin film deposition step is a thin film of silicon, germanium, titanium, tungsten, nickel or copper.
